(19) United States
(12) Patent Application Publication
(10) Pub. No.: US 2026/0020291 A1
(43) Pub. Date: Jan. 15, 2026

(54) SEMICONDUCTOR STRUCTURE AND METHOD FOR MANUFACTURING SEMICONDUCTOR STRUCTURE

(71) Applicant: CXMT Corporation, Hefei City (CN)

(72) Inventors: Mingxu LIU, Hefei City (CN); Hui LI, Hefei City (CN); Jie LI, Hefei City (CN); MIN-HUI CHANG, Hefei City (CN)

(73) Assignee: CXMT Corporation, Hefei City (CN)

(21) Appl. No.: 18/950,037

(22) Filed: Nov. 16, 2024

Related U.S. Application Data
(63) Continuation of application No. PCT/CN2024/119985, filed on Sep. 20, 2024.

(30) Foreign Application Priority Data
Jul. 15, 2024 (CN) 202410948598.0

(51) Int. Cl. H01L 29/06; H10B 12/00

(52) U.S. Cl. CPC H10D 62/102; H10B 12/03; H10D 1/043; H10D 1/716

(57) ABSTRACT

A semiconductor structure includes a substrate, a support structure located above the substrate and capacitor holes spaced apart, wherein the capacitor holes penetrate through the support structure, and lower electrodes located in the capacitor holes, wherein each lower electrode includes a first lower electrode layer, a second lower electrode layer, and a third lower electrode layer. The first lower electrode layer covers the bottom and the side walls of one of the capacitor holes, the second lower electrode layer is conformal to the first lower electrode layer and forms a cavity, and the third lower electrode layer is filled in the cavity, wherein the work function of the second lower electrode layer is greater than the work function of the first lower electrode layer and is greater than the work function of the third lower electrode layer.

### CROSS-REFERENCE TO RELATED APPLICATIONS

This application is a continuation of International Patent Application No. PCT/CN2024/119985 filed on Sep. 20, 2024, which claims priority to Chinese Patent Application No. 202410948598.0 filed on Jul. 15, 2024. The disclosures of the above-referenced applications are hereby incorporated by reference in their entirety.

### BACKGROUND

A dynamic random access memory (DRAM) is a volatile memory and is composed of a plurality of memory cells. Each memory cell mainly includes a transistor and a capacitor structure, and the memory cells are electrically connected to each other through word lines (WLs) and bit lines (BLs).

As the feature size of DRAM continues to decrease, the leakage effect of the capacitor structure becomes more pronounced when the feature size is reduced below a certain numerical value. While ameliorating the leakage effect of the capacitor structure, finding ways to reduce the associated side effects has become an urgent technical issue to be addressed.

It should be noted that the information disclosed in the above background section is only used for enhancement of understanding of the background of the present disclosure, and therefore, may include information that does not constitute some implementations known to those of ordinary skill in the art.

### SUMMARY

The present disclosure relates to the technical field of semiconductors, and in particular, to a semiconductor structure and a method for manufacturing the semiconductor structure.

The present disclosure provides a semiconductor structure and a method for manufacturing the semiconductor structure. The semiconductor structure can improve the leakage performance of the semiconductor structure while reducing the resistance of the semiconductor structure.

Additional features and advantages of the present disclosure will become apparent through the detailed description below or will be learned in part by practice of the present disclosure.

According to one aspect of the present disclosure, a semiconductor structure is provided. The semiconductor structure includes:
a substrate;
a support structure located above the substrate and capacitor holes spaced apart, where the capacitor holes penetrate through the support structure; and
lower electrodes located in the capacitor holes, where each lower electrode includes a first lower electrode layer, a second lower electrode layer, and a third lower electrode layer, where the first lower electrode layer covers a bottom and side walls of one of the capacitor holes, the second lower electrode layer is conformal to the first lower electrode layer and forms a cavity, and the third lower electrode layer is filled in the cavity, where a work function of the second lower electrode layer is greater than a work function of the first lower electrode layer and is greater than a work function of the third lower electrode layer.

According to another aspect of the present disclosure, a method for manufacturing the above semiconductor structure is provided. The method includes:
providing a substrate;
forming a laminated structure on the substrate;
etching the laminated structure to form capacitor holes;
forming a first lower electrode layer, a second lower electrode layer, and a third lower electrode layer in each capacitor hole, where the first lower electrode layer, the second lower electrode layer, and the third lower electrode layer constitute a lower electrode, the first lower electrode layer covers a bottom and side walls of the capacitor hole, the second lower electrode layer is conformal to the first lower electrode layer and forms a cavity, and the third lower electrode layer is filled in the cavity, where a work function of the second lower electrode layer is greater than a work function of the first lower electrode layer and is greater than a work function of the third lower electrode layer.

It should be understood that both the foregoing general description and the following detailed description are exemplary and explanatory only and are not restrictive of the present disclosure.

### BRIEF DESCRIPTION OF THE DRAWINGS

The accompanying drawings herein, which are incorporated in and constitute a part of the specification, illustrate embodiments consistent with the present disclosure and, together with the specification, serve to explain the principles of the present disclosure. It is apparent that the drawings in the description below are only some embodiments of the present disclosure, and for those of ordinary skill in the art, other drawings can be acquired according to these drawings without creative efforts.

FIG. 1 is a schematic cross-sectional diagram of a semiconductor structure according to embodiments of the present disclosure.

FIG. 2 is a flow diagram illustrating steps for a method for manufacturing a semiconductor structure according to embodiments of the present disclosure.

FIG. 3 is a first schematic cross-sectional diagram of a semiconductor structure during its forming process according to some embodiments of the present disclosure.

FIG. 4 is a second schematic cross-sectional diagram of a semiconductor structure during its forming process according to some embodiments of the present disclosure.

FIG. 5 is a third schematic cross-sectional diagram of a semiconductor structure during its forming process according to some embodiments of the present disclosure.

FIG. 6 is a fourth schematic cross-sectional diagram of a semiconductor structure during its forming process according to some embodiments of the present disclosure.

FIG. 7 is a fifth schematic cross-sectional diagram of a semiconductor structure during its forming process according to some embodiments of the present disclosure.

FIG. 8 is a sixth schematic cross-sectional diagram of a semiconductor structure during its forming process according to some embodiments of the present disclosure.

FIG. 9 is a seventh schematic cross-sectional diagram of a semiconductor structure during its forming process according to some embodiments of the present disclosure.

FIG. 10 is an eighth schematic cross-sectional diagram of a semiconductor structure during its forming process according to some embodiments of the present disclosure.

### DETAILED DESCRIPTION

To facilitate understanding of the present disclosure, the present disclosure will be more fully described below with reference to the accompanying drawings. Preferred embodiments of the present disclosure are shown in the accompanying drawings. The present disclosure may, however, be implemented in many different forms and should not be limited to the embodiments described herein. Rather, these embodiments are provided so that the disclosed content of the present disclosure will be more thorough and complete.

As the feature size of DRAM continues to decrease, the leakage effect of the capacitor structure becomes more pronounced when the feature size is reduced below a certain numerical value. While ameliorating the leakage effect of the capacitor structure, finding ways to reduce the associated side effects has become an urgent technical issue to be addressed.

In view of this, the present disclosure provides a semiconductor structure. The semiconductor structure includes a substrate, a support structure located above the substrate and capacitor holes spaced apart, where the capacitor holes penetrate through the support structure, and lower electrodes located in the capacitor holes, where each lower electrode includes a first lower electrode layer, a second lower electrode layer, and a third lower electrode layer. The first lower electrode layer covers the bottom and the side walls of one of the capacitor holes, the second lower electrode layer is conformal to the first lower electrode layer and forms a cavity, and the third lower electrode layer is filled in the cavity, where the work function of the second lower electrode layer is greater than the work function of the first lower electrode layer and is greater than the work function of the third lower electrode layer. The semiconductor structure has a columnar capacitor structure. By providing three-layer lower electrodes, the leakage effect of the columnar capacitor structure is ameliorated, the damage to the second lower electrode layer in the process step is avoided, and the resistance of the columnar capacitor structure is also reduced.

To make the objectives, technical solutions, and advantages of the embodiments of the present disclosure clearer, the technical solutions in the embodiments of the present disclosure are clearly and completely described below with reference to the drawings in the embodiments of the present disclosure, and it is obvious that the described embodiments are a part of the embodiments of the present disclosure, but not all of them. Based on the embodiments of the present disclosure, all other embodiments obtained by those of ordinary skill in the art without creative efforts shall fall within the protection scope of the present disclosure.

FIG. 1 is a schematic cross-sectional diagram of a semiconductor structure according to embodiments of the present disclosure.

Referring to FIG. 1, in one embodiment, a semiconductor structure 100 includes:
a substrate 110, where in actual operation, the substrate 110 includes but is not limited to an elemental semiconductor material substrate (e.g., a silicon (Si) substrate, a germanium (Ge) substrate), a compound semiconductor material substrate (e.g., a germanium-silicon (SiGe) substrate), a silicon-on-insulator (SOI) substrate, or a germanium-on-insulator (GeOI) substrate. The substrate may be doped or undoped, or contain both doped and undoped regions therein. In addition, the material of the substrate 110 may include indium antimonide, lead telluride compound, indium arsenide, indium phosphide, gallium arsenide, or gallium antimonide, but is not limited thereto.

The semiconductor structure 100 includes a support structure 210 located above the substrate 110 and capacitor holes 183 spaced apart, where the capacitor holes 183 penetrate through the support structure 210. The support structure 210 includes a first support layer 120, a second support layer 140, and a third lower support layer 161, where the materials of the first support layer 120, the second support layer 140, and the third lower support layer 161 include but are not limited to a nitride. The materials of the first support layer 120, the second support layer 140, and the third lower support layer 161 may be the same or different. Specifically, the material of the first support layer 120 may be a B-containing insulating material, such as SiBN, and doping with B may reduce the hardness of the material, thereby enabling the capacitor holes 183 formed using an etching method, for example, to exhibit good topography. The material of the second support layer 140 may be a C-containing insulating material, such as SiCN. Since SiCN provides good hardness, the lower electrode 270 can be well supported. The material of the third lower support layer 161 may be a N-containing insulating material, such as silicon nitride.

The semiconductor structure 100 includes lower electrodes 270 located in the capacitor holes 183, where each lower electrode 270 includes a first lower electrode layer 271, a second lower electrode layer 272, and a third lower electrode layer 273. The first lower electrode layer 271 covers the bottom and the side walls of one of the capacitor holes 183, the second lower electrode layer 272 is conformal to the first lower electrode layer 271 and forms a cavity, and the third lower electrode layer 273 is filled in the cavity, where the work function of the second lower electrode layer 272 is greater than the work function of the first lower electrode layer 271 and is greater than the work function of the third lower electrode layer 273.

The work function is an important concept in solid physics, which describes the minimum energy required for electrons to escape from the inside of a solid to a vacuum. The work function is generally represented by the symbol q in the unit of electron volts (eVs). On the metal surface, the work function determines a function of the electron's exit energy of the metal surface, i.e., the energy barrier for the electrons to overcome to transfer from the inside of the metal to a vacuum. A lower work function means that it is easier for electrons to escape, while a higher work function means that it is more difficult for electrons to escape from the metal surface. The leakage of the capacitor structure is directly related to the work function of the electrode material. The higher the work function of the electrode material, the smaller the leakage current of the capacitor structure. In contrast, the electrode material with a low work function may result in poor leakage characteristics in the capacitor structure. The semiconductor structure has a columnar capacitor structure. With the lower electrode 270 configured to be a three-layer structure and the work function of the second lower electrode layer 272 set to be greater than the work function of the first lower electrode layer 271 and greater than the work function of the third lower electrode layer 273, the leakage current effect of the columnar capacitor structure is ameliorated.

In one embodiment, the oxygen content of the second lower electrode layer 272 is greater than the oxygen content of the first lower electrode layer 271 and is greater than the oxygen content of the third lower electrode layer 273. That is, the work function of the electrode material may be increased by doping with the oxygen element. For example, the second lower electrode layer 272 may be TiON; the first lower electrode layer may be TiN or TiSiN, preferably TiSiN; the third lower electrode layer 273 may be TiN. The oxygen content of the material of the second lower electrode layer 272 is greater than the oxygen content of the material of the first lower electrode layer 271 and is greater than the oxygen content of the material of the third lower electrode layer 273.

In one embodiment, the oxygen content of the second lower electrode layer 272 is gradually increased or increased in a gradient manner in the direction from the center to the edge of the capacitor hole. Preferably, the first lower electrode layer 271 may be TiSiN; the third lower electrode layer 273 may be TiN. The oxidation resistance of TiSiN is higher than that of TiN—that is, oxygen atoms are not likely to penetrate into the first lower electrode layer. Therefore, to ensure a high work function of the second lower electrode layer 272, the oxygen content of the second lower electrode layer 272 may be gradually increased or increased in a gradient manner in the direction from the center to the edge of the capacitor hole, thereby reducing the penetration of oxygen atoms into the third lower electrode layer, increasing the resistance of the third lower electrode layer, and ensuring a high work function of the second lower electrode layer 272.

In one embodiment, the conductivity of the third lower electrode layer 273 is greater than the conductivity of the second lower electrode layer 272 and is greater than or equal to the conductivity of the first lower electrode layer 271. Since the second lower electrode layer 272 obtains a high work function by doping with oxygen, the resistivity of the second lower electrode layer 272 is increased accordingly. By provision of the third lower electrode layer 273 with a lower resistivity, the resistance characteristics of the lower electrode 270 may be generally improved, thereby reducing the overall resistance of the lower electrode 270. In addition, the content of the (111) crystal plane of the material in the third lower electrode layer 273 may be greater than 50%, and TiN in the (111) crystal plane has a high work function, such that the leakage current of the capacitor structure may also be reduced by the crystal plane characteristics of the third lower electrode layer 273.

In one embodiment, the material of the third lower electrode layer 273 is different from the material of the first lower electrode layer 271, and the first lower electrode layer 271, the second lower electrode layer 272, and the third lower electrode layer 273 contain a common metal element. Preferably, the first lower electrode layer 271 may be TiSiN; the second lower electrode layer 272 may be TiON; the third lower electrode layer 273 may be TiN. The first lower electrode layer 271, the second lower electrode layer 272, and the third lower electrode layer 273 contain a common metal element, thereby improving the binding performance among the electrode layers, enhancing the conformability of the second lower electrode layer 272 and the first lower electrode layer 271, and reducing both the contact resistance among the electrode layers and the overall resistance of the lower electrode.

In one embodiment, the ratio of the thickness of the first lower electrode layer 271 to the thickness of the second lower electrode layer 272 is in the range of 0.5-0.8. The first lower electrode layer 271, serving as a protective layer for the second lower electrode layer 272, may reduce damage to the second lower electrode layer 272 during the process. Therefore, the ratio of the thickness of the first lower electrode layer 271 to the thickness of the second lower electrode layer 272 should be neither too large nor too small. If the ratio is too large, the resistance of the first lower electrode layer 271 will be increased; if the ratio is too small, the protection of the second lower electrode layer 272 will not be achieved.

In one embodiment, the substrate 110 includes a doped or undoped silicon substrate base 111, capacitor contact structures 112 spaced apart above the silicon substrate base 111, and insulating layers 113 isolating the capacitor contact structures 112; the capacitor hole 183 exposes the top surface of the capacitor contact structure 112, and the capacitor contact structure 112 is electrically connected to the first lower electrode layer 271. The capacitor contact structure 112 may further include a metal silicide, such as titanium silicide (TiSi₂), cobalt silicide (CoSi₂), and nickel silicide (NiSi). The interface between the metal silicide and the silicon substrate base 111 can exhibit good electrical contact, with the contact resistance reduced, and the resistivity of the metal silicide is much lower than that of the silicon substrate base 111, helping to reduce the resistance of the capacitor contact structure 112. Therefore, power consumption is reduced and circuit speed is increased. The material of the insulating layer 113 may be silicon oxide, silicon nitride, silicon oxynitride, silicon oxycarbide, or silicon carbonitride. In this embodiment, the material of the insulating layer 113 is silicon nitride, such that the insulating layer 113 and the first support layer 120 have similar materials, thereby improving the contact effect therebetween.

In one embodiment, the semiconductor structure 100 further includes a dielectric layer 191 covering the lower electrodes 270 and the support structure 210, and an upper electrode 192 covering the dielectric layer 191. In actual operation, the material of the dielectric layer 191 includes but is not limited to aluminum oxide, hafnium oxide, silicon oxide, zirconium oxide, or a combination thereof. The material of the upper electrode 192 includes but is not limited to titanium (Ti), titanium nitride (TiN), or tungsten (W). The above lower electrodes 270, the dielectric layer 191, and the upper electrode 192 jointly constitute a complete columnar capacitor structure.

The semiconductor structure of the present disclosure raises the work function of the second lower electrode layer of the columnar capacitor structure—that is, the leakage current performance of the columnar capacitor structure is improved. Meanwhile, to prevent the second lower electrode layer from being damaged in the forming process of the semiconductor structure, the first lower electrode layer is utilized to protect the second lower electrode layer. In addition, to balance the resistance of the lower electrode, a third lower electrode layer with a lower resistivity is utilized to reduce the overall resistance of the lower electrode.

On the basis of the above embodiments, the embodiments of the present disclosure further provide a manufacturing method for a semiconductor structure (hereinafter referred to as a manufacturing method). The manufacturing method is used for manufacturing the above semiconductor structure 100. The manufacturing method is described in detail below.

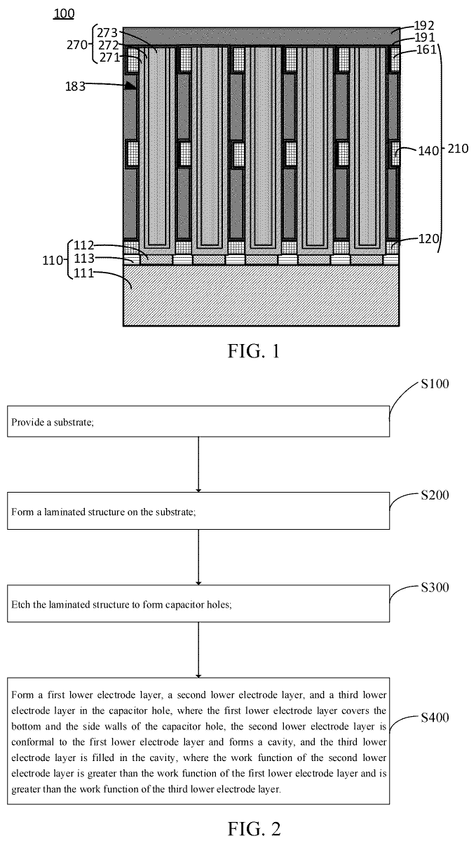

FIG. 2 is a flow diagram illustrating steps for a method for manufacturing a semiconductor structure according to embodiments of the present disclosure.

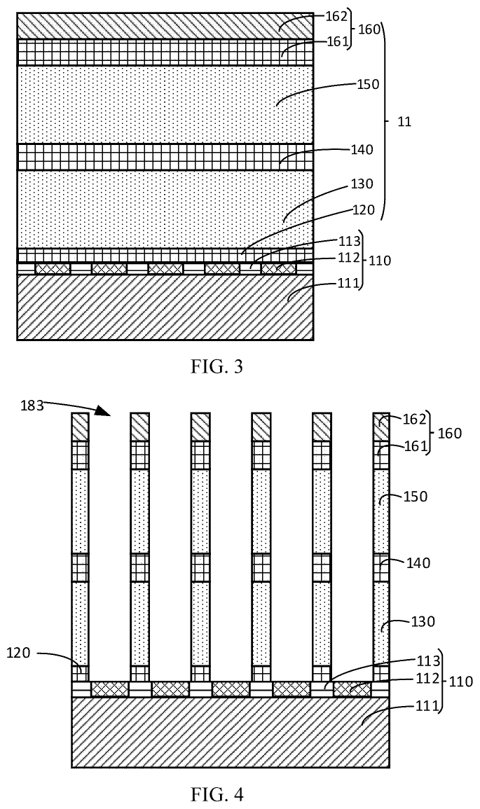

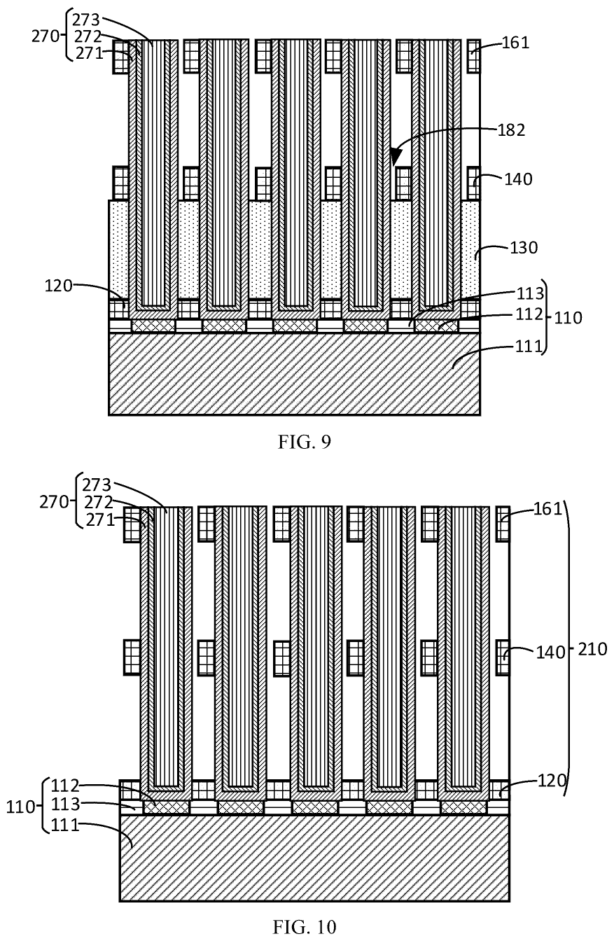

FIGS. 3 to 10 are schematic cross-sectional diagrams of a semiconductor structure during its forming process according to some embodiments of the present disclosure.

Referring to FIG. 2, the method for manufacturing a semiconductor structure includes:

S100: Referring to FIG. 3, a substrate 110 is provided. The substrate 110 includes, for example, but is not limited to, an elemental semiconductor material substrate (e.g., a silicon (Si) substrate, a germanium (Ge) substrate), a compound semiconductor material substrate (e.g., a germanium-silicon (SiGe) substrate), a silicon-on-insulator (SOI) substrate, or a germanium-on-insulator (GeOI) substrate. The substrate may be doped or undoped, or contain both doped and undoped regions therein. In addition, the material of the substrate 110 may include indium antimonide, lead telluride compound, indium arsenide, indium phosphide, gallium arsenide, or gallium antimonide, but is not limited thereto. In addition, the substrate 110 includes a doped or undoped silicon substrate base 111, capacitor contact structures 112 spaced apart above the silicon substrate base 111, and insulating layers 113 isolating the capacitor contact structures 112. The capacitor contact structure 112 may further include a metal silicide, such as titanium silicide (TiSi₂), cobalt silicide (CoSi₂), and nickel silicide (NiSi). The interface between the metal silicide and the silicon substrate base 111 can exhibit good electrical contact, with the contact resistance reduced, and the resistivity of the metal silicide is much lower than that of the silicon substrate base 111, helping to reduce the resistance of the capacitor contact structure 112. Therefore, power consumption is reduced and circuit speed is increased. The material of the insulating layer 113 may be silicon oxide, silicon nitride, silicon oxynitride, silicon oxycarbide, or silicon carbonitride. In this embodiment, the material of the insulating layer 113 is silicon nitride, such that the insulating layer 113 and the first support layer 120 have similar materials, thereby improving the contact effect therebetween.

S200: Referring to FIG. 3, a laminated structure 11 is formed on the substrate 110.

S300: Referring to FIG. 4, the laminated structure 11 is etched to form capacitor holes 183. The capacitor hole 183 exposes the top surface of the capacitor contact structure 112.

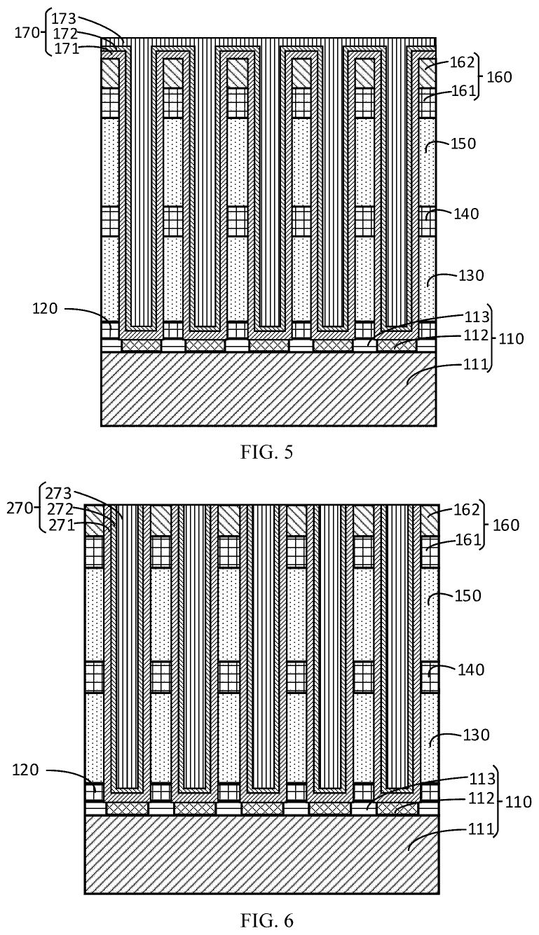

S400: Referring to FIGS. 5 to 6, a first lower electrode layer 271, a second lower electrode layer 272, and a third lower electrode layer 273 are formed in the capacitor hole 183. The first lower electrode layer, the second lower electrode layer, and the third lower electrode layer constitute a lower electrode. The first lower electrode layer 271 covers the bottom and the side walls of the capacitor hole 183, the second lower electrode layer 272 is conformal to the first lower electrode layer 271 and forms a cavity, and the third lower electrode layer 273 is filled in the cavity, where the work function of the second lower electrode layer 272 is greater than the work function of the first lower electrode layer 271 and is greater than the work function of the third lower electrode layer 273.

Referring to FIGS. 3 to 4, in one embodiment, forming the laminated structure 11 on the substrate 110 and etching the laminated structure 11 to form the capacitor holes 183 include:
forming the laminated structure 11 on the substrate 110, where the laminated structure 11 includes at least a first support layer 120, a first sacrificial layer 130, a second support layer 140, a second sacrificial layer 150, and a third support layer 160; and
etching the laminated structure 11 in the direction perpendicular to the substrate 110 to expose the substrate 110 and form the capacitor holes 183.

In actual operation, the first support layer 120, the first sacrificial layer 130, the second support layer 140, the second sacrificial layer 150, and the third support layer 160 may be formed by one or more of the following processes: physical vapor deposition (PVD), chemical vapor deposition (CVD), or atomic layer deposition (ALD) process; the etching of the laminated structure 11 to form the capacitor holes 183 may be performed using an anisotropic etching process, such as a plasma etching process. The materials of the first support layer 120, the second support layer 140, and the third support layer 160 include but are not limited to a nitride. The materials of the first support layer 120, the second support layer 140, and the third support layer 160 may be the same or different. Specifically, the material of the first support layer 120 may be a B-containing insulating material, such as SiBN, and doping with B may reduce the hardness of the material, thereby enabling the capacitor holes 183 formed using an etching method, for example, to exhibit good topography. The material of the second support layer 140 may be a C-containing insulating material, such as SiCN. Since SiCN provides good hardness, the lower electrode 270 can be well supported. The material of the third support layer 160 may be a N-containing insulating material, such as silicon nitride and/or silicon oxynitride. The materials of the first sacrificial layer 130 and the second sacrificial layer 150 may be silicon oxide or B-doped silicon oxide, etc.

Referring to FIGS. 5 to 6, in one embodiment, forming the first lower electrode layer 271, the second lower electrode layer 272, and the third lower electrode layer 273 in the capacitor hole 183, where the first lower electrode layer 271 covers the bottom and the side walls of the capacitor hole 183, the second lower electrode layer 272 is conformal to the first lower electrode layer 271 and forms a cavity, and the third lower electrode layer 273 is filled in the cavity, includes:
forming a first lower electrode material layer 171, where the first lower electrode material layer 171 covers the bottoms and the side walls of the capacitor holes 183 and the upper surface of the laminated structure 11;
forming a second lower electrode material layer 172, where the second lower electrode material layer 172 is conformal to the first lower electrode material layer 171 and the second lower electrode material layer 172 forms cavities in the capacitor holes 183;
forming a third lower electrode material layer 173, where the third lower electrode material layer 173 is filled in the cavities and covers the top part of the second lower electrode material layer 172; and
etching the third lower electrode material layer 173, the second lower electrode material layer 172, and the first lower electrode material layer 171 to expose the third support layer 160, with the remaining parts of the first lower electrode material layer 171, the second lower electrode material layer 172, and the third lower electrode material layer 173 respectively defined as the first lower electrode layer 271, the second lower electrode layer 272, and the third lower electrode layer 273.

In one embodiment, the first lower electrode material layer 171, the second lower electrode material layer 172, and the third lower electrode material layer 173 are respectively deposited using the method of atomic layer deposition (ALD). ALD is an advanced thin film deposition technology that grows thin films layer by layer through precisely controlled chemical reactions. In an ALD process, two or more chemical precursors are used alternately, each time reacting only with the substrate surface in a self-limiting manner to form a single layer of atomic film. These precursors are usually introduced into the reaction chamber in pulses and purged with an inert gas between pulses to ensure complete reaction and removal of the precursors and to avoid vapor reactions between different precursors. The advantages of ALD technology include the ability to control the thickness of thin films with very high precision, to produce excellent thin film uniformity, and to give favorable coverage of complex geometries, and thus depositing electrode material layers using an ALD process can yield excellent results. For example, the first lower electrode material layer 171 is deposited using TiCl₄ (titanium tetrachloride), NH₃ (ammonia), DCS (dichlorosilane, SiH₂Cl₂), SiH₄ (silane) or TiCl₄ (titanium tetrachloride), NH₃ (ammonia) as reaction gases; the second lower electrode material layer 172 is deposited using TiCl₄ (titanium tetrachloride), NH₃ (ammonia), O₂ (oxygen) and O₃ (ozone) as reaction gases; the third lower electrode material layer 173 is deposited by using TiCl₄ (titanium tetrachloride) and NH₃ (ammonia) as reaction gases.

In one embodiment, the oxygen content of the second lower electrode material layer 172 is greater than the oxygen content of the first lower electrode material layer 171 and is greater than the oxygen content of the third lower electrode material layer 173. That is, the work function of the electrode material may be increased by doping with the oxygen element. For example, the second lower electrode material layer 172 may be TiON; the first lower electrode material layer 171 may be TiN or TiSiN, preferably TiSiN; the third electrode material layer 173 may be TiN. The oxygen content of the material of the second lower electrode material layer 172 is greater than the oxygen content of the material of the first lower electrode material layer 171 and is greater than the oxygen content of the material of the third lower electrode material layer 173.

In one embodiment, the oxygen content of the second lower electrode material layer 172 is gradually increased or increased in a gradient manner in the direction from the center to the edge of the capacitor hole. Preferably, the first lower electrode material layer 171 may be TiSiN; the third electrode material layer 173 may be TiN. The oxidation resistance of TiSiN is higher than that of TiN—that is, oxygen atoms are not likely to penetrate into the first lower electrode material layer. Therefore, to ensure a high work function of the second lower electrode material layer 172, the oxygen content of the second lower electrode material layer 172 may be gradually increased or increased in a gradient manner in the direction from the center to the edge of the capacitor hole, thereby reducing the penetration of oxygen atoms into the third lower electrode material layer, increasing the resistance of the third lower electrode material layer, and ensuring a high work function of the second lower electrode material layer 172. In addition, the oxygen content of the second lower electrode material layer 172 may be adjusted by regulating the amount of oxygen input during the atomic layer deposition (ALD) process, so as to obtain the second lower electrode material layer 172 with the oxygen content being gradually increased or increased in a gradient manner in the direction from the center to the edge of the capacitor hole.

In one embodiment, the conductivity of the third lower electrode material layer 173 is greater than the conductivity of the second lower electrode material layer 172 and is greater than or equal to the conductivity of the first lower electrode material layer 171. Since the second lower electrode material layer 172 obtains a high work function by doping with oxygen, the resistivity of the second lower electrode material layer 172 is increased accordingly. By provision of the third lower electrode material layer 173 with a lower resistivity, the resistance characteristics of the lower electrode 270 may be generally improved, thereby reducing the overall resistance of the lower electrode 270. In addition, the content of the (111) crystal plane of the material in the third lower electrode material layer 173 may be greater than 50%, and TiN in the (111) crystal plane has a high work function, such that the leakage current of the capacitor structure may also be reduced by the crystal plane characteristics of the third lower electrode material layer 173.

In one embodiment, the ratio of the thickness of the first lower electrode material layer 171 to the thickness of the second lower electrode material layer 172 is in the range of 0.5-0.8. The first lower electrode material layer 171, serving as a protective layer for the second lower electrode material layer 172, may reduce damage to the first lower electrode material layer 171 during the process. Therefore, the ratio of the thickness of the first lower electrode material layer 171 to the thickness of the second lower electrode material layer 172 should be neither too large nor too small. If the ratio is too large, the resistance of the first lower electrode material layer 171 will be increased; if the ratio is too small, the protection of the second lower electrode material layer 172 will not be achieved.

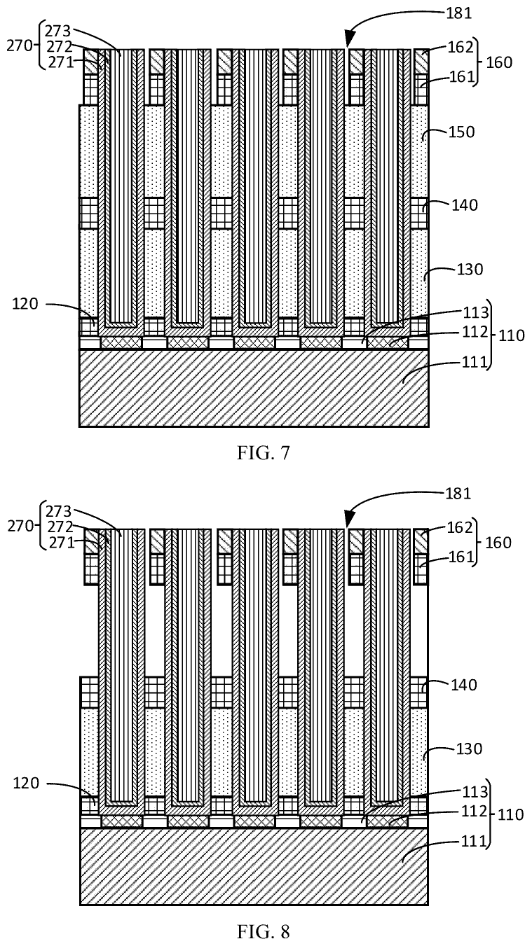

Referring to FIGS. 7 to 10, in one embodiment, the method further includes:
forming first openings 181 in the third support layer 160, where the first openings 181 expose the second sacrificial layer 150. For example, a photoresist is deposited on the third support layer 160 using photolithography or electron beam lithography technology, and a pattern of the desired opening is formed by exposure and development. The exposed third support layer 160 is removed using dry etching (e.g., reactive ion etching-RIE or plasma enhanced chemical vapor deposition-PECVD) to form the first openings 181. After etching, a purging step is used to remove residual photoresist and etching byproducts to ensure a clean surface.

The method then includes removing the second sacrificial layer 150 to expose the second support layer 140. In this step, the second sacrificial layer 150 is removed by a wet etching process.

The method then includes etching the second support layer 140 to form second openings 182, where the second openings 182 expose the first sacrificial layer 130. During the forming process of the second openings 182, the exposed second support layer 140 is removed using dry etching (e.g., reactive ion etching-RIE or plasma enhanced chemical vapor deposition-PECVD).

The method then includes removing the first sacrificial layer 130 to expose the first support layer 120, and the remaining parts of the first support layer, the second support layer, and the third support layer are defined as the support structure 210. In this step, the first sacrificial layer 130 is removed by a wet etching process.

Referring to FIGS. 7 to 10, in one embodiment, the etching selectivity of the first sacrificial layer 130 to the first lower electrode layer 271 is greater than or equal to 5, and the etching selectivity of the second sacrificial layer 150 to the first lower electrode layer 271 is greater than or equal to 5. That is, during the process of removing the first sacrificial layer 130 or the second sacrificial layer 150, wet etching is usually performed using ammonium bifluoride or ammonium fluoride. The etching selectivity of the first sacrificial layer 130 or the second sacrificial layer 150 to the first lower electrode layer 271 is relatively high—that is, during the process of etching the sacrificial layer, the first lower electrode layer 271 will not be significantly etched, thereby ensuring that the first lower electrode layer protects the second lower electrode layer from being damaged by the etching solution and improving the overall performance of the lower electrode.

Referring to FIGS. 7 to 10, in one embodiment, the third support layer 160 includes a third upper support layer 162 and a third lower support layer 161, and during the forming process of the second openings 182, the third upper support layer 162 and a part of the lower electrode are removed by etching. During the process of removing the second sacrificial layer 150, the top part of the second lower electrode layer 272 may be damaged. By removing the damaged second lower electrode layer 272 and the third upper support layer 162 during the forming process of the second openings 182, the complete structure of the lower electrode 270 remains. The material of the third upper support layer 162 may be SiON, and the material of the third lower support layer 161 may be SiN.

Referring to FIG. 1, in one embodiment, the method further includes forming a dielectric layer 191 on the exposed surfaces of the lower electrodes 270 and the support structure 210 and forming an upper electrode 192 on the surface of the dielectric layer 191. In actual operation, the dielectric layer 191 is deposited using an atomic layer deposition process, and the material of the dielectric layer 191 includes but is not limited to aluminum oxide, hafnium oxide, silicon oxide, zirconium oxide, or a combination thereof. The material of the upper electrode 192 includes but is not limited to titanium (Ti), titanium nitride (TiN), or tungsten (W). The deposition method of the upper electrode may be physical vapor deposition (PVD, such as sputtering or evaporation), chemical vapor deposition (CVD, such as atmospheric pressure CVD, low pressure CVD, or plasma enhanced CVD), or atomic layer deposition (ALD). The above lower electrodes 270, the dielectric layer 191, and the upper electrode 192 jointly constitute a complete columnar capacitor structure.

Through the above manufacturing method, the second lower electrode layer with a high work function is selected, thereby improving the leakage current performance of the columnar capacitor structure. In addition, during the process of removing the sacrificial layer, the first lower electrode layer is utilized to protect the side surface of the second lower electrode layer. Meanwhile, the third upper support layer and the third lower support layer, two layers of different materials, are provided, and then the third upper support layer and a part of the lower electrode are selectively removed to achieve an excellent topography of the lower electrode at its top. Therefore, the leakage current performance of the semiconductor structure is improved and the overall resistance requirements for the semiconductor structure are met.

In the description of the present disclosure, it should be understood that orientations or positional relationships indicated by terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, and the like are based on the orientations or positional relationships shown in the drawings, and are used for the convenience of description of the present disclosure only and do not indicate or imply that the device or element referred to must have a particular orientation or be constructed and operated in a particular orientation, and therefore, should not be construed as limitations on the present disclosure.

In the description of the present disclosure, it should be understood that the terms “comprise”, “include”, “have”, and any variations thereof used herein are intended to cover non-exclusive inclusions. For example, a process, method, system, product, or device including a series of steps or units is not necessarily limited to those steps or units explicitly listed, but may include other steps or units not explicitly listed or inherent to the process, method, product, or device.

Unless expressly stated and limited otherwise, the terms “mount”, “link”, “connect”, “fix”, and the like should be understood broadly. For example, it can be a fixed connection, a detachable connection, or integration; it can be directly connected or indirectly connected through an intermediate medium and it can enable the internal connection of two elements or the interaction relationship between two elements. For those of ordinary skill in the art, the specific meanings of the above terms in the present disclosure can be understood according to specific circumstances. Furthermore, the terms “first”, “second”, and the like are only used for the purpose of description and should not be construed as indicating or implying relative importance or implicitly indicating the quantity of the indicated technical features.

Finally, it should be noted that the above embodiments are merely used for illustrating the technical solutions of the present disclosure without limiting the same. Although the present disclosure has been described in detail with reference to the foregoing embodiments, those of ordinary skill in the art should understand that the technical solutions described in the foregoing embodiments may still be modified, or some or all of the technical features may be equivalently replaced. These modifications or replacements do not cause the essence of corresponding technical solutions to depart from the scope of the technical solutions of the embodiments of the present disclosure.

1. A semiconductor structure,
comprising:
a substrate;
a support structure located above the substrate and capacitor holes spaced apart, wherein the capacitor holes penetrate through the support structure; and
lower electrodes located in the capacitor holes, wherein each lower electrode comprises a first lower electrode layer, a second lower electrode layer, and a third lower electrode layer, wherein the first lower electrode layer covers a bottom and side walls of one of the capacitor holes, the second lower electrode layer is conformal to the first lower electrode layer and forms a cavity, and the third lower electrode layer is filled in the cavity, wherein a work function of the second lower electrode layer is greater than a work function of the first lower electrode layer and is greater than a work function of the third lower electrode layer.

2. The semiconductor structure according to claim 1, wherein an oxygen content of the second lower electrode layer is greater than an oxygen content of the first lower electrode layer and is greater than an oxygen content of the third lower electrode layer.

3. The semiconductor structure according to claim 2, wherein the oxygen content of the second lower electrode layer is gradually increased or increased in a gradient manner in a direction from a center to an edge of the capacitor hole.

4. The semiconductor structure according to claim 1, wherein a conductivity of the third lower electrode layer is greater than a conductivity of the second lower electrode layer and is greater than or equal to a conductivity of the first lower electrode layer.

5. The semiconductor structure according to claim 4, wherein a material of the third lower electrode layer is different from a material of the first lower electrode layer, and the first lower electrode layer, the second lower electrode layer, and the third lower electrode layer contain a common metal element.

6. The semiconductor structure according to claim 1, wherein a ratio of a thickness of the first lower electrode layer to a thickness of the second lower electrode layer is in a range of 0.5-0.8.

7. The semiconductor structure according to claim 1, wherein the substrate is further provided with capacitor contact structures spaced apart, each capacitor hole exposes a top surface of one of the capacitor contact structures, and the capacitor contact structure is electrically connected to the first lower electrode layer.

8. The semiconductor structure according to claim 1, further comprising a dielectric layer covering the lower electrodes and the support structure, and an upper electrode covering the dielectric layer.

9. A method for manufacturing a semiconductor structure,
comprising:
providing a substrate;
forming a laminated structure on the substrate;
etching the laminated structure to form capacitor holes;
forming a first lower electrode layer, a second lower electrode layer, and a third lower electrode layer in each capacitor hole, wherein the first lower electrode layer, the second lower electrode layer, and the third lower electrode layer constitute a lower electrode, wherein the first lower electrode layer covers a bottom and side walls of the capacitor hole, the second lower electrode layer is conformal to the first lower electrode layer and forms a cavity, and the third lower electrode layer is filled in the cavity, wherein a work function of the second lower electrode layer is greater than a work function of the first lower electrode layer and is greater than a work function of the third lower electrode layer.

10. The method for manufacturing a semiconductor structure according to claim 9, wherein
forming the laminated structure on the substrate and etching the laminated structure to form the capacitor holes comprise:
forming the laminated structure on the substrate, wherein the laminated structure comprises at least a first support layer, a first sacrificial layer, a second support layer, a second sacrificial layer, and a third support layer; and
etching the laminated structure in a direction perpendicular to the substrate to expose the substrate and form the capacitor holes.

11. The method for manufacturing a semiconductor structure according to claim 10, wherein:
forming the first lower electrode layer, the second lower electrode layer, and the third lower electrode layer in the capacitor hole, wherein the first lower electrode layer covers a bottom and side walls of the capacitor hole, the second lower electrode layer is conformal to the first lower electrode layer and forms a cavity, and the third lower electrode layer is filled in the cavity, comprises:
forming a first lower electrode material layer, wherein the first lower electrode material layer covers bottoms and side walls of the capacitor holes and an upper surface of the laminated structure;
forming a second lower electrode material layer, wherein the second lower electrode material layer is conformal to the first lower electrode material layer and the second lower electrode material layer forms cavities in the capacitor holes;
forming a third lower electrode material layer, wherein the third lower electrode material layer is filled in the cavities and covers a top part of the second lower electrode material layer; and
etching the third lower electrode material layer, the second lower electrode material layer, and the first lower electrode material layer to expose the third support layer, with remaining parts of the first lower electrode material layer, the second lower electrode material layer, and the third lower electrode material layer respectively defined as the first lower electrode layer, the second lower electrode layer, and the third lower electrode layer.

12. The method for manufacturing a semiconductor structure according to claim 10,
further comprising:
forming first openings in the third support layer, wherein the first openings expose the second sacrificial layer;
removing the second sacrificial layer to expose the second support layer;
etching the second support layer to form second openings, wherein the second openings expose the first sacrificial layer; and
removing the first sacrificial layer to expose the first support layer, with remaining parts of the first support layer, the second support layer, and the third support layer defined as a support structure.

13. The method for manufacturing a semiconductor structure according to claim 12, wherein an etching selectivity of the first sacrificial layer to the first lower electrode layer is greater than or equal to 5, and an etching selectivity of the second sacrificial layer to the first lower electrode layer is greater than or equal to 5.

14. The method for manufacturing a semiconductor structure according to claim 12, wherein the third support layer comprises a third upper support layer and a third lower support layer, and during a forming process of the second openings, the third upper support layer and a part of the lower electrode are removed by etching.

15. The method for manufacturing a semiconductor structure according to claim 9, further comprising:
forming a dielectric layer on exposed surfaces of the lower electrodes and a support structure; and
forming an upper electrode on a surface of the dielectric layer.
